(19) United States
(12) Patent Application Publication
(10) Pub. No.: US 2025/0309020 A1
(43) Pub. Date: Oct. 2, 2025

(54) SEMICONDUCTOR DEVICE AND MANUFACTURING METHOD THEREOF

(71) Applicants: Kabushiki Kaisha Toshiba, Tokyo (JP); Toshiba Electronic Devices & Storage Corporation, Tokyo (JP)

(72) Inventor: Saya FUJINO, Kanazawa Ishikawa (JP)

(21) Appl. No.: 18/826,196

(22) Filed: Sep. 6, 2024

(30) Foreign Application Priority Data
Apr. 1, 2024 (JP) 2024-059171

(51) Int. Cl. H01L 23/31; H01L 21/283; H01L 29/40; H01L 29/417; H01L 29/78

(52) U.S. Cl. CPC H01L 23/3192; H01L 21/283; H01L 23/3178; H10D 64/252; H10D 30/668; H10D 64/117

(57) ABSTRACT

A semiconductor device according to the present embodiment includes a semiconductor member, an interlayer film, a metallic layer, and a passivation film. The interlayer film is located on a side of an upper surface of the semiconductor member. The metallic layer is located to cover at least a part of a region on a side of an upper surface of the interlayer film. The passivation film is formed on the upper surface of the interlayer film where the metallic film is not located, and on side surfaces and upper surfaces at end portions of the metallic layer. An upper part of the end portions of the metallic layer has a curved surface.

### CROSS-REFERENCE TO RELATED APPLICATIONS

This application is based upon and claims the benefit of priority from the prior Japanese Patent Application No. 2024-059171, filed on Apr. 1, 2024 the entire contents of which are incorporated herein by reference.

### FIELD

Embodiments of the present invention relate to a semiconductor device and a manufacturing method thereof.

### BACKGROUND

As a semiconductor device for power control and the like to be used in a switching element, a vertical MOSFET (Metal-Oxide-Semiconductor Field-Effect Transistor) has been developed, for example.

In this type of semiconductor device, a passivation film is formed to prevent ingress of water and movable ions.

Meanwhile, there is a case in which a thick electrode is used in a semiconductor device for power control and the like to cause large current to pass through. In such a case, even if a passivation film is formed on metallic layers such as an electrode and a wiring part, a crack is likely to be generated on the passivation film due to a difference in the thermal expansion coefficient from the metallic layers.

### BRIEF DESCRIPTION OF THE DRAWINGS

FIG. 1 is a top view illustrating a semiconductor device according to the present embodiment;

FIG. 2 is a sectional view along a line A-A′ illustrated in FIG. 1;

FIG. 3 is a sectional view along a line B-B′ illustrated in FIG. 1;

FIG. 4 is a sectional view illustrating an end portion of a metallic film;

FIG. 5 is a sectional view illustrating an end portion of a metallic film according to a comparative example;

FIG. 6 is a diagram for explaining stresses applied to the end portion at an upper part; and

FIG. 7A is a diagram illustrating a process of aluminum processing.

FIG. 7B is a diagram illustrating a process of barrier metal processing.

FIG. 7C is a diagram illustrating a process of aluminum shape processing.

FIG. 7D is a diagram illustrating a shaping process of passivation film formation.

### DETAILED DESCRIPTION

According to an embodiment of the present invention, a semiconductor device comprises a semiconductor member, an interlayer film, a metallic layer, and a passivation film. The interlayer film is located on a side of an upper surface of the semiconductor member. The metallic layer is located to cover at least a part of a region on a side of an upper surface of the interlayer film. The passivation film is formed on the upper surface of the interlayer film where the metallic film is not located, and on side surfaces and upper surfaces at end portions of the metallic layer. An upper part of the end portions of the metallic layer has a curved surface.

The semiconductor device and a manufacturing method thereof according to embodiments of the present invention will now be explained below in detail with reference to the drawings. The embodiments described below are only examples of the embodiments of the present invention and are not intended to limit the scope of the present invention. In the drawings referred to in the embodiments, same parts or parts having identical functions are denoted by like or similar reference characters and redundant explanations thereof may be omitted in some cases. Further, there are cases where dimensional ratios of the parts in the drawings are different from those of actual parts and some part of configurations is omitted from the drawings for the sake of explanations.

In the following descriptions and drawings, notations n+, n−, and p represent relative levels of impurity concentrations. That is, a notation with “+” indicates being relatively higher in the impurity concentration than a notation without “+” or “−”, and a notation with “−” indicates being relatively lower in the impurity concentration than a notation without “+” or “−”. In a case in which each region includes both p-type impurities and n− type impurities, the above notations represent relative levels of net impurity concentrations obtained after these impurities have compensated each other. As for embodiments described below, the embodiments may be implemented with the p type and the n type switched in each semiconductor region.

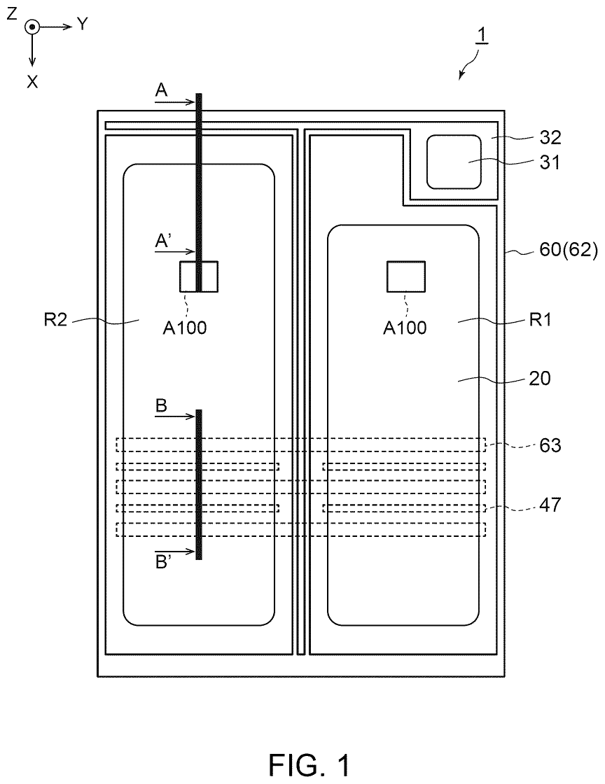

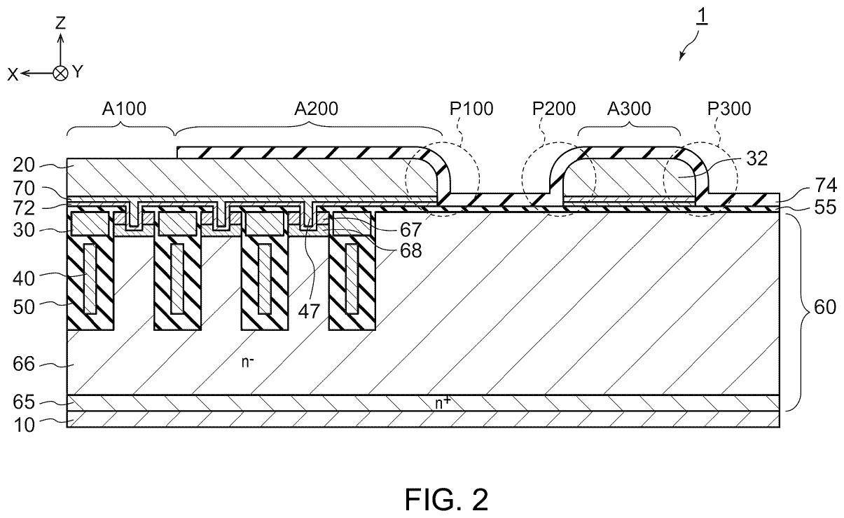

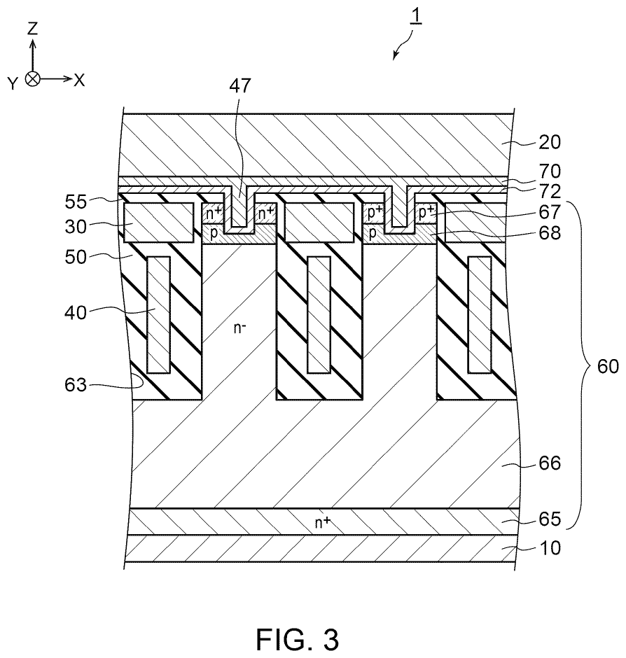

FIG. 1 is a top view illustrating a semiconductor device according to the present embodiment. FIG. 2 is a sectional view along a line A-A′ illustrated in FIG. 1. FIG. 3 is a sectional view along a line B-B′ illustrated in FIG. 1. FIG. 1 is a view schematically illustrating one example of a semiconductor device 1 according to one embodiment.

As illustrated in FIGS. 1, 2, and 3, for example, a vertical MOSFET is constituted in the semiconductor device 1 according to the present embodiment. A drain electrode 10, a source electrode 20, a gate electrode 30, a wiring part 32, an embedded electrode 40, an insulating member 50, an interlayer film 55, a semiconductor member 60, a metallic film 70, a barrier metal layer 72, and a passivation film 74 are provided in the semiconductor device 1. The source electrode 20 and the wiring part 32 according to the present embodiment correspond to a metallic layer. To simplify explanations, illustrations of the passivation film 74 are omitted in FIGS. 1 and 3.

Each of the drain electrode 10, the source electrode 20, the gate electrode 30, and the wiring part 32 is made of a metal. Each of the insulating member 50 and the interlayer film 55 is made of an insulating material. The semiconductor member 60 is made of a semiconductor material.

The semiconductor member 60 is arranged between the drain electrode 10 and the source electrode 20. The gate electrode 30 is arranged in the semiconductor member 60 and extends in a Y direction. The shape of the semiconductor member 60 is, for example, a rectangular plate shape. The semiconductor member 60 has an upper surface on an upper side parallel to an X direction and the Y direction, and a lower surface on a lower side opposite to the upper surface. The semiconductor member 60 is made of, for example, single-crystal silicon (Si) and impurities are locally implanted therein to cause the conductivity type of each portion to be the p type or the n type. The structure of the semiconductor member 60 will be described later. The source electrode 20 according to the present embodiment corresponds to a first electrode, the drain electrode 10 corresponds to a second electrode, and the gate electrode 30 corresponds to a third electrode.

In the present specification, an XYZ orthogonal coordinate system is hereinafter adopted for explanatory convenience. A direction from the drain electrode 10 toward the source electrode 20 is the “Z direction”, a direction in which the gate electrode 30 extends in the present embodiment is the “Y direction”, and a direction orthogonal to the Z direction and the Y direction is the “X direction”. The X direction, the Y direction, and the Z direction are orthogonal to one another. The Z direction is also referred to as “upward”, and the direction opposite thereto is also referred to as “downward”. However, these representations are made for the descriptive purpose and are irrelevant to the direction of gravity.

As illustrated in FIG. 1, a gate pad 31 and the wiring part 32 in the form of a frame are provided on an outer edge portion of an upper surface 62 of the semiconductor member 60. The gate pad 31 is provided, for example, on one corner portion of the upper surface 62 of the semiconductor member 60. The wiring part 32 is connected to the gate pad 31. In the present specification, “connection” means electrical connection.

The source electrode 20 is arranged on a region surrounded by the gate pad 31 and the wiring part 32 on the upper surface 62 of the semiconductor member 60. The source electrode 20 is provided on each of regions R1 and R2. For example, the source electrode 20 provided on the region R1 and the source electrode 20 provided on the region R2 are connected to each other by a bonding wire, a connector, or the like, to be connected to a bonding region A100 at the time of package assembly, and are used as a single electrode. The source electrode 20 is isolated from the gate pad 31 and the wiring part 32. The drain electrode 10 is arranged on the whole of the lower surface of the semiconductor member 60.

As illustrated in FIGS. 1 to 3, a plurality of trenches 63 are formed on the semiconductor member 60 from the side of the upper surface 62. Each of the trenches 63 extends in the Y direction. The trenches 63 are arrayed along the X direction. The trenches 63 do not reach the lower surface of the semiconductor member 60. The insulating member 50 is arranged in each of the trenches 63. An upper part of each of the insulating members 50 is protruded upward from the upper surface 62 of the semiconductor member 60 and extends to the both sides of the associated trench 63 in the X direction to form the interlayer film 55. However, two insulating members 50 and two interlayer films 55 adjacent in the X direction are both isolated from each other. The insulating members 50 and the interlayer films 55 include, for example, either silicon oxide or silicon nitride. Each of the insulating members 50 and the associated interlayer film 55 may be formed either integrally or not integrally.

The metallic film 70 is provided between the interlayer films 55 and the source electrode 20 and between the semiconductor member 60 and the source electrode 20. The metallic film 70 covers upper surfaces and side surfaces of the interlayer films 55 and covers the upper surface of the semiconductor member 60 between adjacent ones of the interlayer films 55. The metallic film 70 is in contact with the source electrode 20 and is connected to the source electrode 20.

A trench contact 47 of the metallic film 70 is formed between adjacent ones of the interlayer films 55. Each of the trench contacts 47 extends in the Y direction. The trench contacts 47 are arrayed along the X direction.

The barrier metal layer 72 covers a lower surface side of the metallic film 70 including side surfaces thereof. The barrier metal layer 72 prevents diffusion of metallic atoms to the side of the semiconductor member 60 or an interaction between members that are adjacent across the barrier metal layer 72. The barrier metal layer 72 is, for example, a tungsten (W) or titanium (Ti) film, a titanium nitride film (TiN), or a stacked metallic film including these films.

The passivation film 74 is formed on the upper surface of the source electrode 20. The bonding region A100 exposed on an opening portion of the passivation film 74 functions as a bonding region for source lines. The source electrode 20 is formed to an end portion of a terminal cell A200 outside of the bonding region A100.

Similarly, also in a wiring region A300, the passivation film 74 is formed on the upper surface of the wiring part 32. Also under the wiring part 32, the metallic film 70 and the barrier metal layer 72 are stacked on the upper surface of the interlayer film 55 in the same manner as under the source electrode 20. As will be described later, for example, the wiring part 32 and the metallic film 70 may be integrated. Alternatively, it is permissible that the wiring part 32 and the metallic film 70 are not integrated.

Upper parts of end portions of metallic layers such as the source electrode 20 and the wiring part 32 on which the passivation film 74 is formed, for example, an end portion P100 of the source electrode 20, and end portions P200 and P300 of the wiring region A300 have a configuration including a curved surface. For example, the upper parts of the end portions of the metallic layers have an arc shape. Details of the end portions P100, P200, and P300 will be described later.

As described above, at least either the wiring part 32 and the metallic film 70, or the source electrode 20 and the metallic film 70 is also referred to as “metallic layer (32(20))”. The metallic layer (32(20)) may be formed integrally with the metallic film 70 or not integrally therewith. As described above, the semiconductor device 1 according to the present embodiment includes the semiconductor member 60, the interlayer film 55 located on the side of the upper surface of the semiconductor member 60, the metallic layer (32(20)) located to cover at least a part of a region of the interlayer film 55 on the side of the upper surface thereof, and the passivation film 74 formed on a portion of the upper surface of the interlayer film 55 where the metallic layer (32(20)) is not located, and the side surfaces and the upper surface at end portions of the metallic layer (32(20)). The upper part at the end portions of the metallic layer (32(20)) has an arc shape.

The gate electrode 30 is arranged in each of the trenches 63. The gate electrodes 30 are isolated from the semiconductor member 60 with a part of the insulating member 50 interposed therebetween. Both end portions of each of the gate electrodes 30 in the Y direction are drawn up to the upper surface 62 of the semiconductor member 60 and are connected to the wiring part 32. Accordingly, the gate electrodes 30 are connected to the gate pad 31 via the wiring part 32.

The insulating member 50 is, for example, silicon dioxide (SiO₂), silicon nitride (Si₃N₄), PSG (Phospho Silicate Glass), BPSG (Boron Phospho Silicate Glass), or SOG (Spin On Glass) as an inorganic material and is any of various polymers including polyimide as an organic material.

A plurality of embedded electrodes 40 are arranged below the gate electrodes 30 in the trenches 63. The embedded electrodes 40 are intermittently arrayed in lines along the Y direction. In other words, a plurality of the embedded electrodes 40 are provided along the Y direction. A part of the insulating member 50 is arranged between embedded electrodes 40 adjacent in the Y direction. The embedded electrodes 40 include silicon and are made of, for example, polysilicon with impurities implanted therein. The embedded electrodes 40 are isolated from the gate electrodes 30 with a part of the insulating member 50 interposed therebetween.

The embedded electrodes 40 are in contact with the metallic film 70. Accordingly, the embedded electrodes 40 are connected to the source electrode 20 via the metallic film 70.

The metallic film 70 and the source electrode 20 are, for example, integrally formed. The metallic film 70 and the source electrode 20 are, for example, aluminum (Al) or a high-strength aluminum alloy (AlCu). The metallic film 70 and the source electrode 20 include at least one metal selected from a group including aluminum (Al), a high-strength aluminum alloy (AlCu), copper (Cu), tungsten (W), titanium (Ti), cobalt (Co), and nickel (Ni) and may include, for example, a metal compound or an alloy including any metal in the above metal group.

Similarly, the metallic film 70 and the wiring part 32 are, for example, integrally formed. The metallic film 70 and the wiring part 32 are, for example, aluminum (Al) or a high-strength aluminum alloy (AlCu). The metallic film 70 and the wiring part 32 include at least one metal selected from a group including aluminum (Al), a high-strength aluminum alloy (AlCu), copper (Cu), tungsten (W), titanium (Ti), cobalt (Co), and nickel (Ni) and may include, for example, a metal compound or an alloy including any metal in the above metal group.

As described above, the insulating member 50 and the interlayer film 55 are arranged between the semiconductor member 60 and the gate electrodes 30, between the gate electrodes 30 and the embedded electrodes 40, between the gate electrodes 30 and the metallic film 70, and between the semiconductor member 60 and the embedded electrodes 40.

In the semiconductor member 60, a drain layer 65 of the n+ type conductivity, a drift layer 66 of the n− type conductivity, a source layer 67 of the n+ type conductivity, and a base layer 68 of the p type conductivity are provided. The carrier concentration of the source layer 67 is higher than those of the drain layer 65 and the drift layer 66. In the descriptions, “carriers” are electrons and holes. The drain layer 65 constitutes a lower surface 61 of the semiconductor member 60 and is arranged between the drain electrode 10 and the drift layer 66. Accordingly, the drift layer 66 is connected to the drain electrode 10 via the drain layer 65. The source layer 67 constitutes the upper surface 62 of the semiconductor member 60 and is in contact with the metallic film 70. Accordingly, the source layer 67 is connected to the source electrode 20 via the metallic film 70.

The base layer 68 is arranged between the drift layer 66 and the source layer 67 and is in contact with the drift layer 66 and the source layer 67. The base layer 68 is connected to the source electrode 20 via the metallic film 70.

An operation of the semiconductor device 1 according to the present embodiment is explained next.

A voltage that causes the potential of the drain electrode 10 to be higher than the potential of the source electrode 20 is applied between the drain electrode 10 and the source electrode 20. When a potential higher than a threshold is applied to the gate electrodes 30 in this state, an inversion layer (a channel) is formed in a region of the base layer 68 in contact with the insulating member 50. Accordingly, electrons flow from the source electrode 20 through the metallic film 70, the source layer 67, the inversion layer formed in the base layer 68, the drift layer 66, and the drain layer 65 to the drain electrode 10. As a result, the semiconductor device 1 is brought to an on-state and current flows from the drain electrode 10 to the source electrode 20.

When the potential of the gate electrodes 30 becomes lower than the threshold, the inversion layer formed in the base layer 68 disappears and a depletion layer extends from a pn interface between the drift layer 66 and the base layer 68 as the starting point. Since the same potential as that to the source electrode 20 is also applied to the embedded electrodes 40, the depletion layer also extends from a surface of the drift layer 66 being in contact with the insulating member 50. That is, in the drift layer 66, the depletion layer extends downward from the pn interface and extends in the X direction from the insulating member 50. Accordingly, the semiconductor device 1 is brought to an off-state and current from the drain electrode 10 toward the source electrode 20 is interrupted.

When the semiconductor device 1 is switched from the on-state to the off-state, the voltage between the source electrode 20 and the drain electrode 10 rapidly increases. The potential of the source electrode 20 also propagates to the embedded electrodes 40 through the metallic film 70. With switching of the semiconductor device 1 to the off-state and increase in the potential of the embedded electrodes 40, the insulating member 50 functions as a parasitic capacitance between the embedded electrodes 40 and the drain electrode 10 and change/discharge of electrons occurs. Accordingly, the voltage between the source electrode 20 and the drain electrode 10 oscillates and then converges to a predetermined voltage.

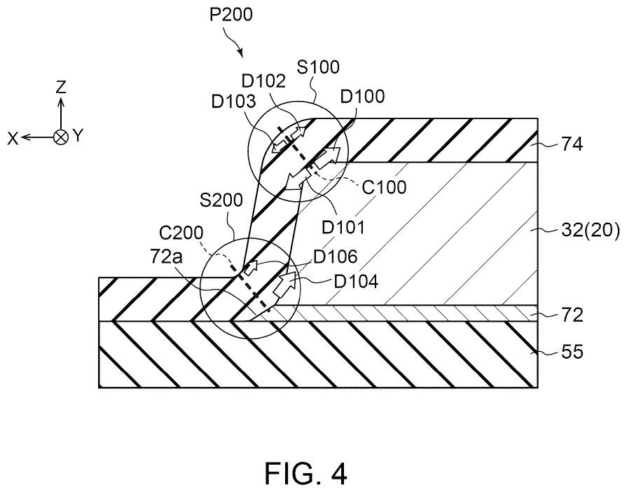

Detailed configuration examples of the end portions P100, P200, and P300 (see FIG. 2) of the metallic film on which the passivation film 74 is formed are described below. FIG. 4 is a view illustrating the end portion P200 in an enlarged manner. As described above, the end portions P200 and P300 are examples in the wiring part 32. However, the end portion P100 of the source electrode 20 also has substantially the same configuration. As described above, the wiring part 32 and the source electrode 20 may have the metallic film 70. The wiring part 32 and the source electrode 20 may be constituted of metallic materials different from that of the metallic film 70. In this case, the wiring part 32 and the source electrode 20 are stacked bodies including different metallic materials.

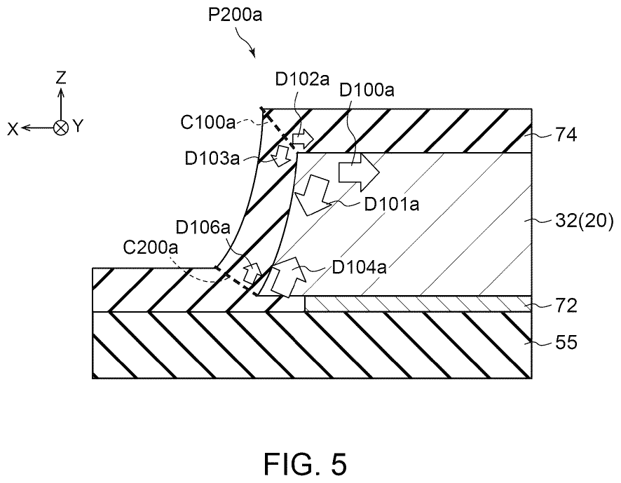

FIG. 5 is a sectional view illustrating a configuration example of an end portion P200a according to a comparative example. Stresses D100 to D106 in FIG. 4 represent stresses on the passivation film 74 generated at the time of thermal treatment. Similarly, stresses D100a to D106a in FIG. 5 represent stresses on the passivation film 74 generated at the time of thermal treatment. That is, since the thermal expansion coefficient of the wiring part 32 (the source electrode 20) is larger than that of the passivation film 74, stresses are generated at the time of thermal treatment.

As illustrated in FIG. 4, the end portion P200 according to the present embodiment is different from the end portion P200a according to the comparative example in including a first relaxation region S100 and a second relaxation region S200 for stresses. As illustrated in FIG. 5, at the end portion P200a according to the comparative example, the stresses D100a to D103a are likely to be concentrated in the upper part of the end portion of the wiring part 32 (the source electrode 20). The end portion of the barrier metal layer 72 has a rectangular shape and the stresses D104a to D106a are likely to be concentrated in the lower part of the end portion of the wiring part 32 (the source electrode 20).

For example, the stress D101a and the stress D104a, and the stress D103a and the stress D106a are stresses in the opposing directions. Accordingly, a force in a compressing direction is applied between crack lines C100a and C200a. The stress D101a and the stress D100a, and the stress D103a and the stress D102a, which are stresses in the opposing directions are generated on the crack line C100a. Accordingly, a stress in a direction of breaking away the crack line C100a is generated. In this way, as the stresses D100a to D103a increase, the force in the direction of breaking away the crack line C100a increases.

When the stress D104a and the stress D106a increase, a crack along the crack lines C100a and C200a is likely to be generated due to interactions between the stress D101a and the stress D104a and between the stress D103a and the stress D106a.

In contrast thereto, in the first relaxation region S100, the end portion at the upper part has a curved surface to prevent generation of an edge on the wiring part 32 (the source electrode 20). Accordingly, the stresses D100 to D103 concentrated in the end portion at the upper part of the wiring part 32 (the source electrode 20) are relaxed. As described above, with the end portion at the upper part having a curved surface, the stresses D100 to D103 are relaxed and occurrence of a crack along the crack line C100 is suppressed.

In the second relaxation region S200, the end portion of the barrier metal layer 72 is formed in a trapezoidal shape. Accordingly, the stresses D104 to D106 concentrated in the end portion at the lower part of the wiring part 32 (the source electrode 20) are relaxed. With this formation of the end portion of the barrier metal layer 72 in a trapezoidal shape, the stresses D104 to D106 are relaxed and occurrence of a crack along the crack lines C100 and C200 is suppressed. That is, the barrier metal layer 72 has a shape where a surface on the lower side in contact with the interlayer film 55 is longer than a surface on the upper side in contact with the metallic layer (32(20)).

As described above, an end face 72a of the barrier metal layer 72 formed between the lower surface of the metallic layer (32(20)) and the upper surface of the interlayer film 55 is inclined. That is, the end face 72a of the barrier metal layer 72 on the side of the end portion of the metallic layer (32(20)) has a shape inclined from the side of the end portion toward the other end portion as approaching from the interlayer film 55 to the lower surface of the end portion of the metallic layer (32(20)). With this inclination of the end face 72a of the barrier metal layer 72, the stresses D104 to D106 are relaxed and occurrence of a crack along the crack lines C100 and C200 is suppressed.

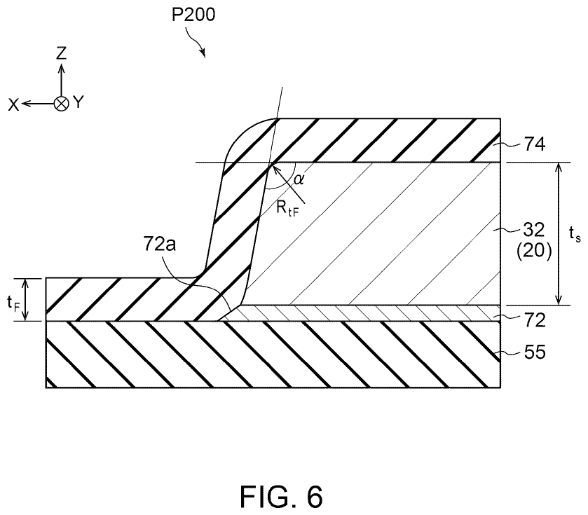

A range of an arc-shaped radius Rt_{F} is described below with reference to FIG. 6. FIG. 6 is a diagram for explaining stresses applied to the end portion at the upper part. In this example, the radius of an arc of the end portion at the upper part is Rt_{F}, the metal thickness of the wiring part 32 (the source electrode 20) is tₛ, and the film thickness of the passivation film 74 is t_{F}. That is, the metallic layer (32(20)) has an upper surface and a lower surface parallel to a first direction (the X direction) and a second direction (the Y direction) orthogonal to the first direction, and the metal thickness tₛ is the distance between the upper surface and the lower surface. Similarly, the passivation film 74 has an upper surface and a lower surface parallel to the first direction (the X direction) and the second direction (the Y direction) orthogonal to the first direction, and the film thickness t_{F} of the passivation film 74 is the distance between the upper surface and the lower surface. As described above, the end portion at the upper part of the metallic layer (32(20)) has a curved surface. For example, an angle α at which extended lines of the upper surface and the side surface of the end portion at the upper part cross each other is formed to be equal to or more than 90 degrees.

Two types of stresses, that is, a membrane stress σ and a thermal stress σT are applied to the arc of the radius Rt_{F} of the end portion at the upper part of the wiring part 32 (the source electrode 20). As described above, the passivation film 74 cracks because thermal treatment is performed after formation, and a difference in the thermal expansion coefficient between the underlying wiring part 32 (the source electrode 20) and the passivation film 74 is large. The stress is generated because the thermal stress σT is large. That is, no crack is generated at the time of formation of the passivation film 74 and it is considered that a crack is generated when the thermal stress σT becomes larger than the membrane stress σ. In other words, the arc shape of the radius Rt_{F} according to the present embodiment is a shape that enables the thermal stress σT on the passivation film 74 to be smaller than the membrane stress σ. That is, the arc shape of the radius Rt_{F} is a shape that enables to relax the thermal stress σT on the passivation film 74.

As described above, the arc shape according to the present embodiment has a predetermined radius Rt_{F}. The predetermined radius Rt_{F} is a radius that enables the thermal stress σT on the passivation film 74 to be smaller than the membrane stress σ. The range of the radius Rt_{F} meeting a relation: the membrane stress σ≈the thermal stress σT is examined below. According to the Stoney's formula, the membrane stress σ is represented by expression (1).

A more specific example is described, where the material of the wiring part 32 (the source electrode 20) is aluminum (Al) and the material of the passivation film 74 is silicon dioxide (SiO₂).

$$σ = \frac{{E}_{S} {t}_{S}^{2}}{6 ( 1 - {v}_{s} ) {Rt}_{F}} \qquad expression ( 1 )$$

$${σ}_{T} = \frac{Δσ}{Δ T} = \frac{{E}_{F} ( {α}_{F} - {α}_{s} )}{1 - {v}_{F}} \qquad expression ( 2 )$$

In this example, Eₛ is the Young's modulus (70 GPa) of aluminum (Al) and E_{F} is the Young's modulus (73 GPa) of silicon dioxide (SiO₂). Accordingly, calculation is performed assuming that Eₛ˜E_{F}. Vₛ is the Poisson's ratio (0.33) of aluminum (Al) and V_{F} is the Poisson's ratio (0.17) of silicon dioxide (SiO₂). Furthermore, aₛ is the thermal expansion coefficient (22 to 23.5×10\hat{ }−6/° C.) of aluminum (Al) and a_{F} is the thermal expansion coefficient (0.41 to 0.58×10\hat{ }−6/° C.) of silicon dioxide (SiO₂).

When values are substituted in expression (1), expression (3) is obtained.

$$\begin{matrix}[ Formula 3 ] & \\ σ = \frac{{{t}_{s}}^{2} \times {E}_{s}}{6 ( 1 - 0.33 ) \times {Rt}_{F}} & expression ( 3 )\end{matrix}$$

When values are substituted in expression (2), expression (4) is obtained.

$$\begin{matrix}[ Formula 4 ] & \\ σ T = \frac{{a}_{F} - {a}_{s}}{0.83} \times {E}_{F} = \frac{\vert - 21.5 \sim - 23 \vert}{0.83} \times {E}_{S} = 25.9 \sim 27.7 \times {E}_{S} & expression ( 4 )\end{matrix}$$

Accordingly, when expression (4) is further substituted in expression (3), expression (5) is obtained.

$$\begin{matrix}[ Formula 5 ] & \\ \frac{{{t}_{s}}^{2} \times {E}_{s}}{4.02 \times {Rt}_{F}} ≅ 25.9 \sim 27.7 \times {E}_{s} & expression ( 5 )\end{matrix}$$

Expression (6) is obtained by rearranging expression (5).

$$\begin{matrix}[ Formula 6 ] & \\ {Rt}_{F} ( min ) = \frac{{{t}_{s}}^{2}}{4.02 \times 27.7 \times {t}_{F}} = \frac{{{t}_{s}}^{2}}{110.8 \times {t}_{F}} & expression ( 6 )\end{matrix}$$

As is understood from these expressions, when the metallic layer (32(20)) is aluminum (Al) and the passivation film 74 is silicon dioxide (SiO₂), the predetermined radius Rt_{F} according to the present embodiment has a value larger than a value obtained by dividing a value, which is obtained by dividing the square of the thickness tₛ of the metallic layer (32(20)) by the thickness t_{F} of the passivation film 74, by 110.8 being a predetermined constant. In the semiconductor device 1 according to the present embodiment, for example, the thickness of the wiring part 32 (the source electrode 20) is 4 micrometers (μm) and the thickness of the passivation film 74 is 1 μm. In this case, tₛ:t_{F}=4:1. By substituting this relation in expression (6), the radius Rt_{F} is calculated based on expression (7).

$$\begin{matrix}[ Formula 7 ] & \\ {Rt}_{F} ( min ) = \frac{1}{110.8} \times \frac{16 {{t}_{F}}^{2}}{{t}_{F}} ≅ 0.14 μm & expression ( 7 )\end{matrix}$$

As is understood from this expression, in a case in which the thickness of the wiring part 32 (the source electrode 20) is 4 μm and the thickness of the passivation film 74 is 1 μm, occurrence of a crack is suppressed when the radius Rt is set to be equal to or more than 0.14 μm.

In the present embodiment, the thickness of aluminum (Al) in the wiring part 32 (the source electrode 20) is 3 to 6 μm and the thickness of the passivation film 74 is 0.5 to 1.5 μm. As is understood from this, the radius Rt_{F} becomes 0.65 μm being the largest value when the thickness of aluminum (Al) is 6 μm and the thickness of silicon dioxide (SiO₂) is 0.5 μm.

Meanwhile, the radius Rt_{F} becomes 0.041 μm being the smallest value when the thickness of aluminum (Al) is 3 μm and the thickness of silicon dioxide (SiO₂) is 1.5 μm. That is, occurrence of a crack is suppressed when the radius Rt_{F} according to the present embodiment is equal to or more than 41 to 650 nanometers (nm).

Particularly, when occurrence of a crack is to be suppressed, the radius Rt_{F} is set to be equal to or more than 100 to 650 nm in a case in which the thickness tₛ of the metallic film (32(20)) is 3 to 6 μm and the thickness t_{F} of the passivation film 74 is 0.5 to 1.5 μm.

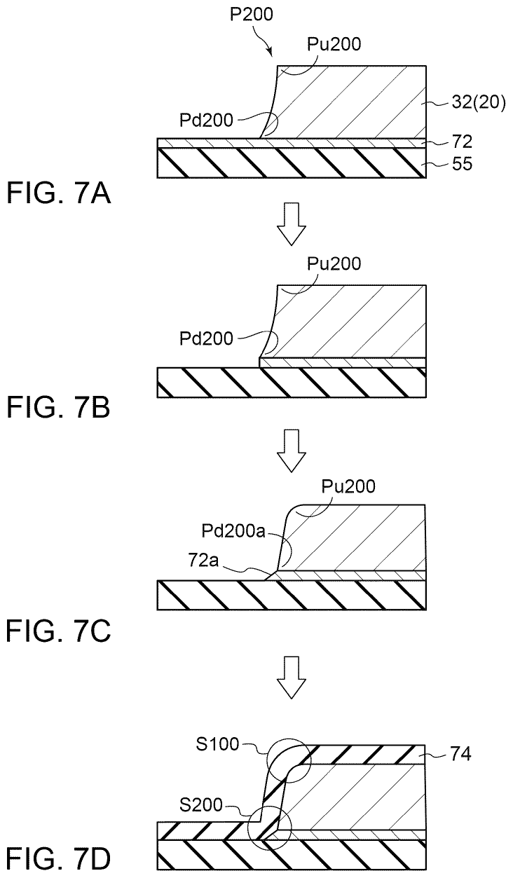

A manufacturing example of the first relaxation region S100 and the second relaxation region S200 of the end portion P200 is explained below with reference to FIG. 7. FIG. 7 are diagrams illustrating a manufacturing method of the first relaxation region S100 and the second relaxation region S200 of the end portion P200.

FIG. 7A is a diagram illustrating a process of aluminum processing. As illustrated in FIG. 7A, the barrier metal layer 72 and the metallic layer (32(20)) are formed on the interlayer film 55 (the insulating material 50). Next, the metallic layer (32(20)) is processed by a method of removing an unnecessary portion through a chemical reaction by wet etching (WET). Accordingly, the process of aluminum processing is a process of stacking the interlayer film 55, the barrier metal layer 72, and the metallic layer (32(20)) on the side of the upper surface of the semiconductor member 60 and processing the metallic layer (32(20)) to generate end portion regions Pu200 and Pd200. This processing may be dry etching by reactive ion etching. The metallic layer (32(20)) may either include or not include the metallic film 70.

FIG. 7B is a diagram illustrating a process of barrier metal processing. As illustrated in FIG. 7B, the barrier metal layer 72 is processed. For example, an unnecessary portion of the barrier metal layer 72 is removed through a chemical reaction by wet etching (WET). Accordingly, the process of barrier metal processing is a process of processing the barrier metal layer 72 to the lower end portion region Pd200 of the metallic layer (32(20)). This process may be dry etching by reactive ion etching.

FIG. 7C is a diagram illustrating a process of aluminum shape processing. As illustrated in FIG. 7C, through a chemical reaction by wet etching (WET), the metallic layer (32(20)) is set back and an arc of the radius Rt_{F} is generated on the end portion Pu200 at the upper part. At that time, the end portion of the barrier metal layer 72 is processed into a trapezoidal shape by etching at the time of setting back the metallic layer (32(20)). For example, in a case in which the barrier metal layer 72 is made of tungsten and an etchant such as phosphoric acid is used, the metallic layer and the barrier metal layer can be processed at an etching rate ratio of 10:1. With use of this difference in the etching rate, the end portion of the barrier metal layer 72 can be processed into a trapezoidal shape. In this way, the process of aluminum shape processing is a process of forming a predetermined arc shape in the upper end portion region Pu200 of the metallic layer (32(20)) while processing the lower end portion region Pd200 toward the end portion on the other side to form the inclined surface 72a corresponding to the position of the lower end portion region Pd200a on the barrier metal layer 72. This process may be dry etching by reactive ion etching.

FIG. 7D is a diagram illustrating a shaping process of passivation film formation. As illustrated in FIG. 7D, the passivation film 74 is formed by chemical vapor deposition. After being formed, the passivation film 74 is processed by reactive ion etching. By this manufacturing method, the first relaxation region S100 and the second relaxation region S200 are formed.

As described above, according to the present embodiment, in a case in which the barrier metal layer 72, the metallic layer (the wiring part 32 and the source electrode 20), and the passivation film 74 are formed on the interlayer film 55, a curved surface (for example, an arc shape having the predetermined radius Rt_{F}) is formed in the upper end portion region Pu200 of the metallic layer (the wiring part 32 and the source electrode 20). Accordingly, stresses generated on the passivation film 74 at the time of thermal treatment are relaxed due to the arc shape and occurrence of a crack on the passivation film 74 is suppressed. The shape of the end face 72a of the barrier metal layer 72 is inclined from the side of an end portion toward the other end portion as approaching from the interlayer film 55 to the lower surface of the end portion of the metallic layer (the wiring part 32 and the source electrode 20). Accordingly, stresses generated on the passivation film 74 at the time of thermal treatment are relaxed in the lower end portion region Pd200a of the metallic layer (the wiring part 32 and the source electrode 20) and occurrence of a crack at an end portion (in the relaxation region S200) of the lower part of the passivation film 74 and an end portion (in the relaxation region S100) of the upper part thereof is suppressed.

While certain embodiments have been described above, these embodiments have been presented by way of example only, and are not intended to limit the scope of the inventions. Indeed, the novel devices, methods, and programs described in the present specification may be embodied in a variety of other forms; furthermore, various omissions, substitutions, and changes in the form of the devices, methods, and programs described herein may be made without departing from the spirit of the inventions.

1. A semiconductor device comprising:
a semiconductor member;
an interlayer film located on a side of an upper surface of the semiconductor member;
a metallic layer located to cover at least a part of a region on a side of an upper surface of the interlayer film; and
a passivation film located on the upper surface of the interlayer film where the metallic film is not located, and on side surfaces and upper surfaces at end portions of the metallic layer, wherein
an upper part of the end portions of the metallic layer has a curved surface.

2. The device of claim 1, further comprising a barrier metal layer having a shape in which a surface on a lower side in contact with the interlayer film is longer than a surface on an upper side in contact with the metallic layer.

3. The device of claim 2, wherein an end face of the barrier metal layer on a side of each of the end portions has a shape inclined from the side of the end portion toward another end portion as approaching from the interlayer film to a lower surface of the end portion of the metallic layer.

4. The device of claim 1, wherein the curved surface of the upper part has a shape where an angle α at which extended lines of the upper surface and the side surface at each of the end portions of the metallic layer cross each other is equal to or more than 90 degrees to enable a thermal stress on the passivation film to be smaller than a membrane stress.

5. The device of claim 1, wherein the curved surface of the upper part is of an arc shape and has a shape that enables to relax a thermal stress on the passivation film in the arc shape.

6. The device of claim 1, wherein the curved surface of the upper part is of an arc shape and the arc shape has a predetermined radius.

7. The device of claim 6, wherein the predetermined radius is a radius that enables a thermal stress on the passivation film to be smaller than a membrane stress.

8. The device of claim 6, wherein
the metallic layer has an upper surface and a lower surface parallel to a first direction, and a second direction orthogonal to the first direction, and
the predetermined radius is equal to or more than a thickness of the metallic layer being a distance between the upper surface and the lower surface.

9. The device of claim 7, wherein the predetermined radius has a value larger than a value obtained by dividing a value, which is obtained by dividing a square of a thickness of the metallic layer by a thickness of the passivation film, by a predetermined constant when the metallic layer is aluminum and the passivation film is silicon dioxide.

10. The device of claim 9, wherein the predetermined radius is equal or more than 100 to 650 nanometers (nm) when the thickness of the metallic layer is 3 to 6 micrometers (μm) and the thickness of the passivation film is 0.5 to 1.5 μm.

11. The device of claim 2, wherein the metallic layer is an electrode or a wiring part.

12. The device of claim 1, wherein
the metallic layer is a first electrode, and
the device further comprises
a second electrode located on a lower surface of the semiconductor member, and
a third electrode located in the semiconductor member and along a first direction from the first electrode to the second electrode.

13. A manufacturing method of a semiconductor device, the method comprising:
stacking an interlayer film, a barrier metal layer, and a metal layer on a side of an upper surface of a semiconductor member, and processing the metallic layer to generate an end portion region;
processing the barrier metal layer to the end portion region of the metallic layer;
forming a predetermined arc shape at an end portion on an upper part of the end portion region while processing the end portion region toward an end portion on another side to form an inclined surface corresponding to a position of the end portion region on the barrier metal layer; and
forming a passivation film on the metallic layer processed and the inclined surface of the barrier metal layer.

14. The method of claim 13, wherein the barrier metal layer is formed to have an inclined surface having a shape where a lower surface in contact with the interlayer film is longer than an upper surface in contact with the metallic layer.

15. The method of claim 14, wherein an end face of the barrier metal layer on a side of each of the end portions has a shape inclined from the side of the end portion toward another end portion as approaching from the interlayer film to a lower surface of the end portion of the metallic layer.

16. The method of claim 13, wherein the arc shape has a shape where an angle α at which extended lines of an upper surface and a side surface of the metallic layer in the end portion region cross each other is equal to or more than 90 degrees to enable a thermal stress on the passivation film to be smaller than a membrane stress.

17. The method of claim 13, wherein the arc shape has a shape that enables to relax a thermal stress on the passivation film.

18. The method of claim 13, wherein the arc shape has a predetermined radius.

19. The method of claim 18, wherein the predetermined radius is a radius that enables a thermal stress on the passivation film to be smaller than a membrane stress.

20. The method of claim 18, wherein
the metallic layer has an upper surface and a lower surface parallel to a first direction, and a second direction orthogonal to the first direction, and
the predetermined radius is equal to or more than a thickness of the metallic layer being a distance between the upper surface and the lower surface.
